(19) United States
(12) Patent Application Publication
(10) Pub. No.: US 2024/0321594 A1
(43) Pub. Date: Sep. 26, 2024

(54) EMBEDDED MAGNET FRAME, INTEGRATED STRUCTURE AND MANUFACTURING METHOD

(71) Applicant: Zhuhai ACCESS Semiconductor Co., Ltd., Guangdong (CN)

(72) Inventors: Xianming CHEN, Guangdong (CN); Xiaowei XU, Guangdong (CN); Yejie HONG, Guangdong (CN); Benxia HUANG, Guangdong (CN); Gao HUANG, Guangdong (CN); Dongfeng ZHANG, Guangdong (CN); Jindong FENG, Guangdong (CN)

(73) Assignee: Zhuhai ACCESS Semiconductor Co., Ltd., Guangdong (CN)

(21) Appl. No.: 18/612,661

(22) Filed: Mar. 21, 2024

(30) Foreign Application Priority Data
Mar. 21, 2023 (CN) 2023102869218

(51) Int. Cl. H01L 21/48; H01L 21/56; H01L 21/683; H01L 23/00; H01L 23/31; H01L 23/498

(52) U.S. Cl. CPC H01L 21/486; H01L 21/568; H01L 21/6835; H01L 23/3121; H01L 23/49827; H01L 24/24; H01L 24/82; H01L 2221/68345; H01L 2224/24155; H01L 2224/82106

(57) ABSTRACT

An embedded magnet frame, an integrated structure and a manufacturing method are disclosed. The manufacturing method includes: manufacturing conductive metal columns, a first sacrificial block and a second sacrificial block on a surface of a bearing plate; laminating a first dielectric layer on the surface of the bearing plate so that the first dielectric layer covers the conductive metal columns, the first sacrificial block and the second sacrificial block; thinning the first dielectric layer to expose surfaces of the conductive metal columns, the first sacrificial block and the second sacrificial block; etching the first sacrificial block and the second sacrificial block to form corresponding first and second mounting cavities, the second mounting cavity being used for mounting a chip; filling the first mounting cavity with magnetic slurry to form an embedded magnet; and removing the bearing plate to form an embedded magnet frame.

### CROSS-REFERENCE TO RELATED APPLICATION

This application is filed on the basis of copending Chinese Patent Application No. 2023102869218, filed Mar. 21, 2023, and claims the benefit and priority of the Chinese patent application, the entire contents of which are incorporated herein by reference.

### TECHNICAL FIELD

The present disclosure relates to the technical field of semiconductor packaging, and in particular to an embedded magnet frame, an integrated structure and a manufacturing method.

### BACKGROUND

With the continuous development of electronic technology, there is an increasing demand for higher performance and smaller size in electronic products. Consequently, the trend towards high-density integration and miniaturization of packaging substrates and structures for electronic products has become inevitable. At present, the surface mounting process is mainly used for packaging magnetic devices. However, due to the relatively large size of magnetic devices, this packaging method results in a larger volume for the packaged devices, which cannot meet the requirements for miniaturization and high integration. Moreover, due to the need for secondary surface mounting, the production process and production costs will increase.

### SUMMARY

The present disclosure aims to solve at least one of the technical problems in the existing technology. To this end, the present disclosure proposes an embedded magnet frame, an integrated structure and a manufacturing method, which are beneficial to achieving miniaturization and high integration of packaged products, and saving production processes and production costs.

In an aspect, a manufacturing method for an embedded magnet frame according to an embodiment of the present disclosure includes manufacturing conductive metal columns, a first sacrificial block and a second sacrificial block on a surface of a bearing plate; laminating a first dielectric layer on the surface of the bearing plate so that the first dielectric layer covers the conductive metal columns, the first sacrificial block and the second sacrificial block; thinning the first dielectric layer to expose surfaces of the conductive metal columns, the first sacrificial block and the second sacrificial block; etching the first sacrificial block and the second sacrificial block to form corresponding first and second mounting cavities, the second mounting cavity being used for mounting a chip; filling the first mounting cavity with magnetic slurry to form an embedded magnet; and removing the bearing plate to form an embedded magnet frame.

According to some embodiments of the present disclosure, the bearing plate comprises a substrate, and a first metal layer, a second metal layer and a third metal layer that are sequentially stacked on a surface of the substrate, and the first metal layer and the second metal layer are capable of being physically separated.

According to some embodiments of the present disclosure, the first metal layer and the second metal layer are copper layers, and the third metal layer is a titanium layer.

According to some embodiments of the present disclosure, the manufacturing conductive metal columns, a first sacrificial block and a second sacrificial block on a surface of a bearing plate includes applying a photoresist layer on the surface of the bearing plate; performing exposure and development process om the photoresist layer to form patterns corresponding to the conductive metal columns, the first sacrificial block and the second sacrificial block; and forming, according to the patterns, the conductive metal columns, the first sacrificial block and the second sacrificial block by electroplating.

According to some embodiments of the present disclosure, the filling the first mounting cavity with magnetic slurry to form an embedded magnet includes filling the magnetic slurry into the first mounting cavity by means of screen printing, and solidifying, grounding and polishing the magnetic slurry to form the embedded magnet.

In another aspect, a manufacturing method for an embedded magnet integrated structure according to an embodiment of the present disclosure includes mounting a chip inside a second mounting cavity of an embedded magnet frame, the embedded magnet frame being manufactured by the manufacturing method for an embedded magnet frame as described in the embodiment of the above aspect; packaging the chip with a photosensitive resin film, and making the photosensitive resin film cover upper and lower surfaces of the first dielectric layer; opening windows in the photosensitive resin film on the upper and lower surfaces of the first dielectric layer to form first windows; and forming first circuits by electroplating at the first windows, the first circuit on the upper surface of the first dielectric layer and the first circuit on the lower surface of the first dielectric layer being connected by the conductive metal columns.

According to some embodiments of the present disclosure, the following steps are further included providing second dielectric layers respectively on upper and lower surfaces of the photosensitive resin film; manufacturing solder masks on surfaces of the second dielectric layers, and opening windows in the solder masks to form second windows; and forming second circuits by electroplating at the second windows, the second circuits being connected with the first circuits through metal blind holes extending through the second dielectric layers.

In another aspect, an embedded magnet frame according to an embodiment of the present disclosure includes a first dielectric layer provided with a first mounting cavity and a second mounting cavity that extend through the first dielectric layer, the second mounting cavity being used for mounting a chip; conductive metal columns extending through the first dielectric layer; and an embedded magnet provided inside the first mounting cavity.

In another aspect, an embedded magnet integrated structure according to an embodiment of the present disclosure includes the embedded magnet frame as described in the embodiment of the above aspect; a chip arranged in the second mounting cavity; a photosensitive resin film filled in the second mounting cavity to fix the chip, the photosensitive resin film covering upper and lower surfaces of the first dielectric layer; and first circuits, the photosensitive resin film on the upper and lower surfaces of the first dielectric layer being respectively opened with first windows, the first circuits being arranged in the first windows, and the first circuit on the upper surface of the first dielectric layer and the first circuit on the lower surface of the first dielectric layer being connected by the conductive metal columns.

According to some embodiments of the present disclosure, the embedded magnet integrated structure further includes second dielectric layers provided on upper and lower surfaces of the photosensitive resin film, the second dielectric layers being provided with metal blind holes extending through the second dielectric layers; solder masks provided on surfaces of the second dielectric layers, the solder masks being provided with second windows; and second circuits provided in the second windows, the second circuits being electrically connected to the first circuits through the metal blind holes.

### BRIEF DESCRIPTION OF DRAWINGS

The above and/or additional aspects and advantages of the present disclosure will become apparent and readily understood from the description of the embodiments taken in conjunction with the following accompanying drawings, in which:

FIG. 1 is a flowchart of a manufacturing method for an embedded magnet frame according to an embodiment of the present disclosure;

FIG. 2 is a schematic structural diagram of a bearing plate according to an embodiment of the present disclosure;

FIG. 3 is a schematic structural diagram after manufacturing conductive metal columns, a first sacrificial block and a second sacrificial block on a surface of the bearing plate;

FIG. 4 is a schematic structural diagram after a first dielectric layer is laminated on the surface of the bearing plate and the first dielectric layer is thinned;

FIG. 5 is a schematic structural diagram after the first sacrificial block and the second sacrificial block are etched away;

FIG. 6 is a schematic structural diagram after the first mounting cavity is filled with magnetic slurry;

FIG. 7 is a schematic structural diagram of an embedded magnet frame according to an embodiment of the present disclosure;

FIG. 8 is a top view of the embedded magnet frame according to an embodiment of the present disclosure;

FIG. 9 is a flowchart of a manufacturing method for an embedded magnet integrated structure according to an embodiment of the present disclosure;

FIG. 10 is a flowchart of the manufacturing method for an embedded magnet integrated structure according to another embodiment of the present disclosure;

FIG. 11 is a schematic structural diagram after a bearing film is provided at the bottom of the embedded magnet frame;

FIG. 12 is a schematic structural diagram after a chip is mounted inside a second mounting cavity;

FIG. 13 is a schematic structural diagram after the bearing film is removed;

FIG. 14 is a schematic structural diagram of the chip after being packaged with the photosensitive resin film;

FIG. 15 is a schematic structural diagram of the photosensitive resin film after being opened with windows;

FIG. 16 is a schematic structural diagram after seed layer production and electroplating filling after opening windows;

FIG. 17 is a schematic structural diagram of the embedded magnet integrated structure according to an embodiment of the present disclosure; and

FIG. 18 is a schematic structural diagram of the embedded magnet integrated structure according to another embodiment of the present disclosure.

### DETAILED DESCRIPTION

This section will describe the example embodiments of the present disclosure in detail. Embodiments of the present disclosure are shown in the accompanying drawings. The function of the accompanying drawings is to supplement the description of the text part of the specification with graphics, enabling intuitive and vivid understanding of each technical feature and overall technical solution of the present disclosure, and shall not be construed as limiting the scope of protection of the present disclosure.

In the description of the present disclosure, it should be understood that, the orientation or positional relationships indicated by the terms such as upper, lower, front, rear, left, right, etc., are based on the orientation or positional relationships shown in the accompanying drawings, merely for ease of description of the present disclosure and simplification for the description, rather than indicating or implying that the device or element referred to must have a specific orientation and be constructed and operated in a specific orientation, which, therefore, cannot be construed as limiting the present disclosure.

In the description of the present disclosure, several refers to one or more; a plurality of refers to two or more; greater than, less than, over and the like are understood not to include the following number, and above, below, within and the like are understood to include the following number. If described, the terms such as first and second are only for the purpose of distinguishing technical features, and not to be construed as indicating or implying relative importance or implicitly indicating the number of technical features indicated or implicitly indicating the precedence relationship of technical features indicated.

In the description of the present disclosure, unless otherwise explicitly limited, providing, installing, connecting and other words should be understood broadly, and a person of ordinary skills in the art can reasonably determine the specific meaning of the above words in the present disclosure combined with the specific content of the technical solution.

The embedded magnet frame, integrated structure and manufacturing method provided in the embodiments of the present disclosure have at least the following beneficial effects. When manufacturing a frame, the magnet is already embedded inside the frame, eliminating the need for secondary mounting of magnetic devices on the surface of a packaging substrate, thereby saving production processes and production costs. Moreover, the embedded magnet is provided inside a first dielectric layer, which is beneficial to achieving miniaturization and high integration of packaged products.

Additional aspects and advantages of the present disclosure will be set forth in part in the description which follows, and in part will be obvious from the description, or may be learned by practice of the present disclosure.

### REFERENCE NUMERALS

bearing plate 100, substrate 110, first metal layer 120, second metal layer 130, third metal layer 140, conductive metal column 200, first sacrificial block 300, first mounting cavity 310, second sacrificial block 400, second mounting cavity 410, first dielectric layer 500, chip 600, embedded magnet 700, embedded magnet frame 800, bearing film 900, photosensitive resin film 1000, first window 1100, first circuit 1200, second dielectric layer 1300, solder mask 1400, second circuit 1500, and metal blind hole 1600.

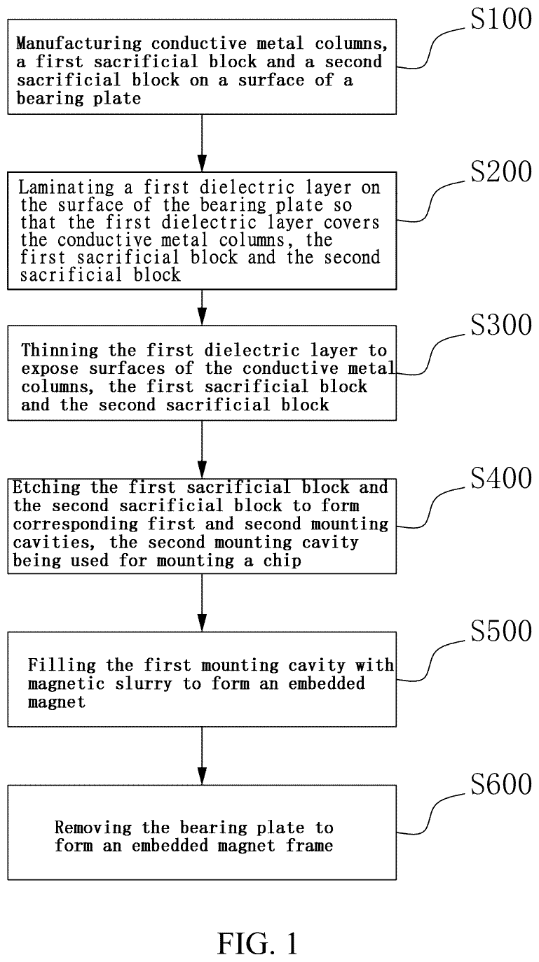

In an aspect, as shown in FIG. 1, an embodiment of the present disclosure provides a manufacturing method for an embedded magnet frame, including:
Step S100: manufacturing conductive metal columns 200, a first sacrificial block 300 and a second sacrificial block 400 on a surface of a bearing plate 100;
Step S200: laminating a first dielectric layer 500 on the surface of the bearing plate 100 so that the first dielectric layer 500 covers the conductive metal columns 200, the first sacrificial block 300 and the second sacrificial block 400;
Step S300: thinning the first dielectric layer 500 to expose surfaces of the conductive metal columns 200, the first sacrificial block 300 and the second sacrificial block 400;
Step S400: etching the first sacrificial block 300 and the second sacrificial block 400 to form corresponding first mounting cavity 310 and second mounting cavity 410, the second mounting cavity 410 being used for mounting a chip 600;
Step S500: filling the first mounting cavity 310 with magnetic slurry to form an embedded magnet 700; and
Step S600: removing the bearing plate 100 to form an embedded magnet frame 800.

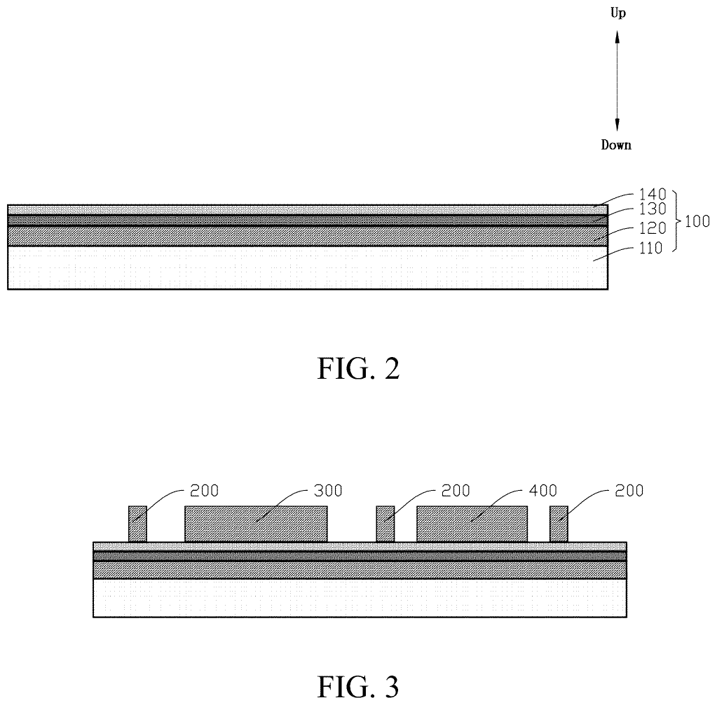

Referring to FIG. 2, in some embodiments of the present disclosure, the bearing plate 100 includes a substrate 110, and a first metal layer 120, a second metal layer 130 and a third metal layer 140 that are sequentially stacked on the surface of the substrate 110, and the first metal layer 120 and the second metal layer 130 can be physically separated. It should be noted that the first metal layer 120, the second metal layer 130 and the third metal layer 140 may be provided on the upper surface of the substrate 110, may also be provided on the lower surface of the substrate 110, or may be provided on the upper and lower surfaces of the substrate 110 (this can facilitate the subsequent manufacturing of two embedded magnet frames 800 at the same time). For convenience of explanation, in this example, the case where the first metal layer 120, the second metal layer 130 and the third metal layer 140 are provided on the upper surface of the substrate 110 is taken as an example. The first metal layer 120 and the second metal layer 130 are both copper layers and are physically combined to facilitate separation in subsequent operations; while the third metal layer 140 is a titanium layer. When the bearing plate 100 is subsequently removed, the first metal layer 120 and the second metal layer 130 need to be separated first, then the second metal layer 130 and the third metal layer 140 are etched away, and the third metal layer 140 serves to prevent excessive etching.

In order to manufacture the conductive metal columns 200, the first sacrificial block 300 and the second sacrificial block 400 on the surface of the bearing plate 100, step S100 may include:
Step S101: applying a photoresist layer on the surface of the bearing plate 100;
Step S102: performing exposure and development process on the photoresist layer to form patterns corresponding to the conductive metal columns 200, the first sacrificial block 300 and the second sacrificial block 400; and
Step S103: according to the patterns, forming the conductive metal columns 200, the first sacrificial block 300 and the second sacrificial block 400 by electroplating. The conductive metal columns 200, the first sacrificial block 300 and the second sacrificial block 400 are usually made of copper, and may also be made of other metal materials.

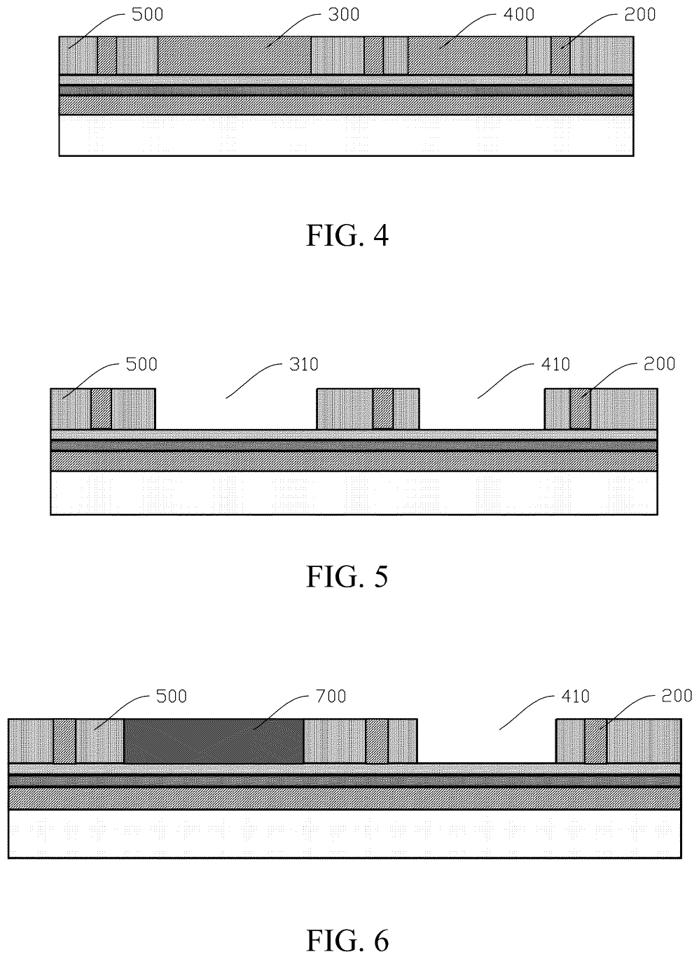

As shown in FIGS. 3 and 4, after the conductive metal columns 200, the first sacrificial block 300 and the second sacrificial block 400 are manufactured, the first dielectric layer 500 is laminated onto the surface of the bearing plate 100 by means of lamination. The first dielectric layer 500 may be an ordinary resin film or a resin film containing glass fiber (the resin film containing glass fiber is conducive to improving the rigidity of the packaging substrate). The thickness of the first dielectric layer 500 needs to be higher than that of the conductive metal columns 200, the first sacrificial block 300 and the second sacrificial block 400, so as to cover the conductive metal columns 200, the first sacrificial block 300 and the second sacrificial block 400. Subsequently, the first dielectric layer 500 is thinned by means of mechanical grinding etc., so as to expose the surfaces of the conductive metal columns 200, the first sacrificial block 300 and the second sacrificial block 400.

Subsequently, as shown in FIG. 5, both the first sacrificial block 300 and the second sacrificial block 400 are etched away to form corresponding first mounting cavity 310 and second mounting cavity 410. As shown in FIG. 6, magnetic slurry is filled into the first mounting cavity 310 by means of screen printing, and the magnetic slurry is solidified, ground and polished to form an embedded magnet 700.

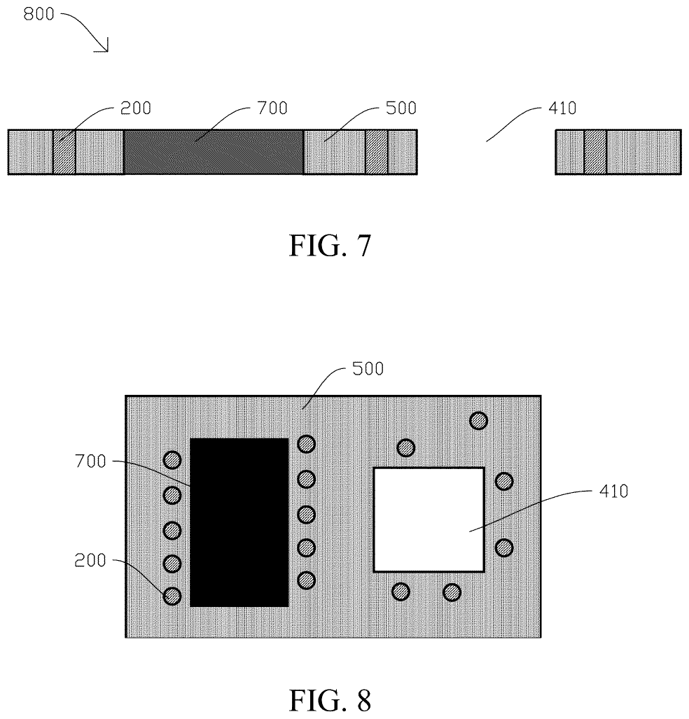

Finally, as shown in FIGS. 7 and 8, the bearing plate 100 is removed, and the remaining part forms the embedded magnet frame 800. In order to remove the bearing plate 100, the plate is first split to separate the first metal layer 120 and the second metal layer 130, and then the second metal layer 130 and the third metal layer 140 are etched away to thus remove the bearing plate 100.

In the manufacturing method for an embedded magnet frame according to an embodiment of the present disclosure, the embedded magnet 700 is already embedded inside the frame while the frame is being manufactured, thereby eliminating the need for subsequent secondary mounting of magnetic devices on the surface of the packaging substrate and saving production processes and production costs. Moreover, the embedded magnet 700 is provided inside the first dielectric layer 500, which is beneficial to achieving miniaturization and high integration of packaged products.

In another aspect, corresponding to the manufacturing method for an embedded magnet frame in the above embodiments, the present disclosure further provides an embedded magnet frame 800. As shown in FIGS. 7 and 8, the embedded magnet frame 800 includes a first dielectric layer 500, conductive metal columns 200 and an embedded magnet 700. The first dielectric layer 500 is provided with a first mounting cavity 310 and a second mounting cavity 410 that extend through the first dielectric layer 500. The embedded magnet 700 is provided inside the first mounting cavity 310. The interior of the second mounting cavity 410 is used for mounting a chip. The conductive metal columns 200 extend through the first dielectric layer 500.

In the embedded magnet frame according to an embodiment of the present disclosure, the embedded magnet 700 is provided inside the first dielectric layer 500 and is provided with a second mounting cavity 410 that can be used for mounting a chip 600, which is beneficial to achieving miniaturization and high integration of packaged products.

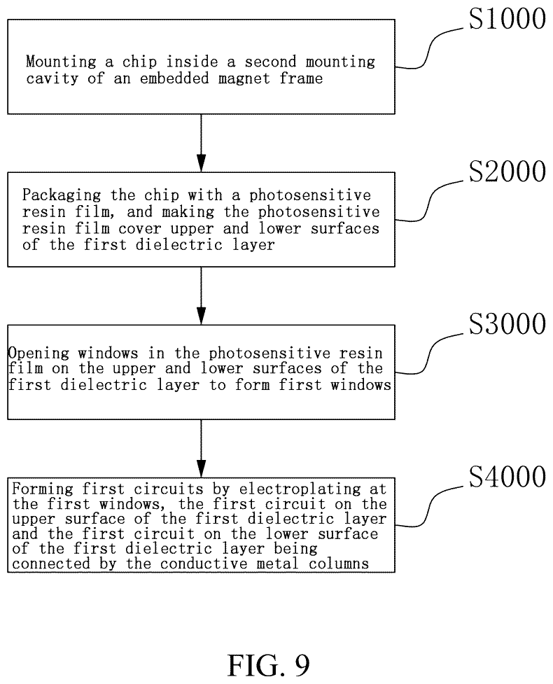

In another aspect, an embodiment of the present disclosure further provides a manufacturing method for an embedded magnet integrated structure. As shown in FIG. 9, the method includes the following steps:
Step S1000: mounting a chip 600 inside a second mounting cavity 410 of an embedded magnet frame 800, the embedded magnet frame 800 being manufactured by the above manufacturing method for an embedded magnet frame;
Step S2000: packaging the chip 600 with a photosensitive resin film 1000, and making the photosensitive resin film 1000 cover the upper and lower surfaces of a first dielectric layer 500;
Step S3000: opening windows in the photosensitive resin film 1000 on upper and lower surfaces of the first dielectric layer 500 to form first windows 1100; and
Step S4000: forming first circuits 1200 by electroplating at the first windows 1100, the first circuit 1200 on the upper surface of the first dielectric layer 500 and the first circuit 1200 on the lower surface of the first dielectric layer 500 being connected by the conductive metal columns 200.

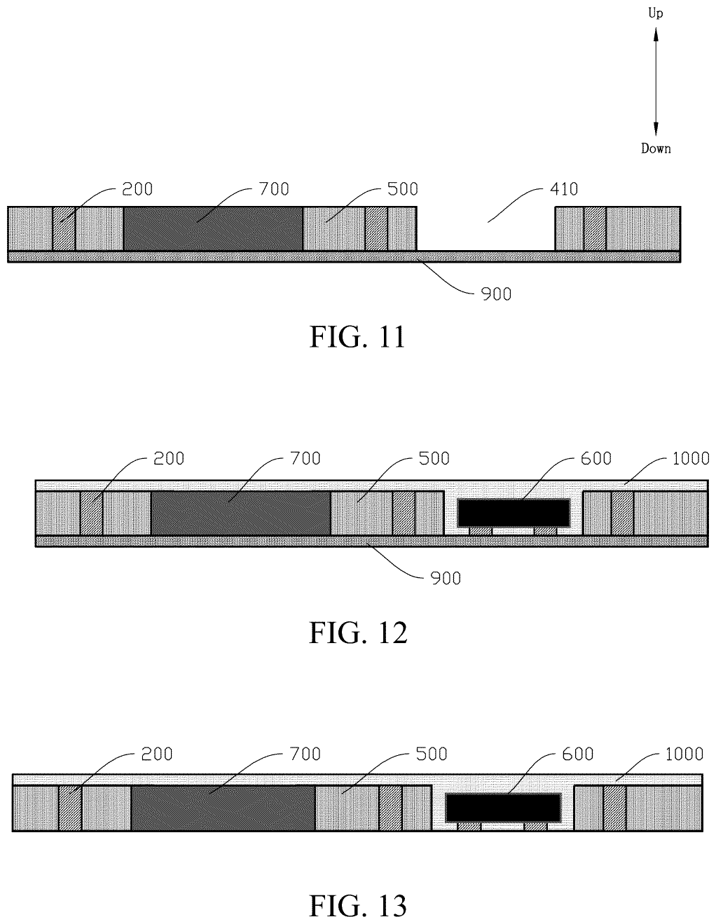

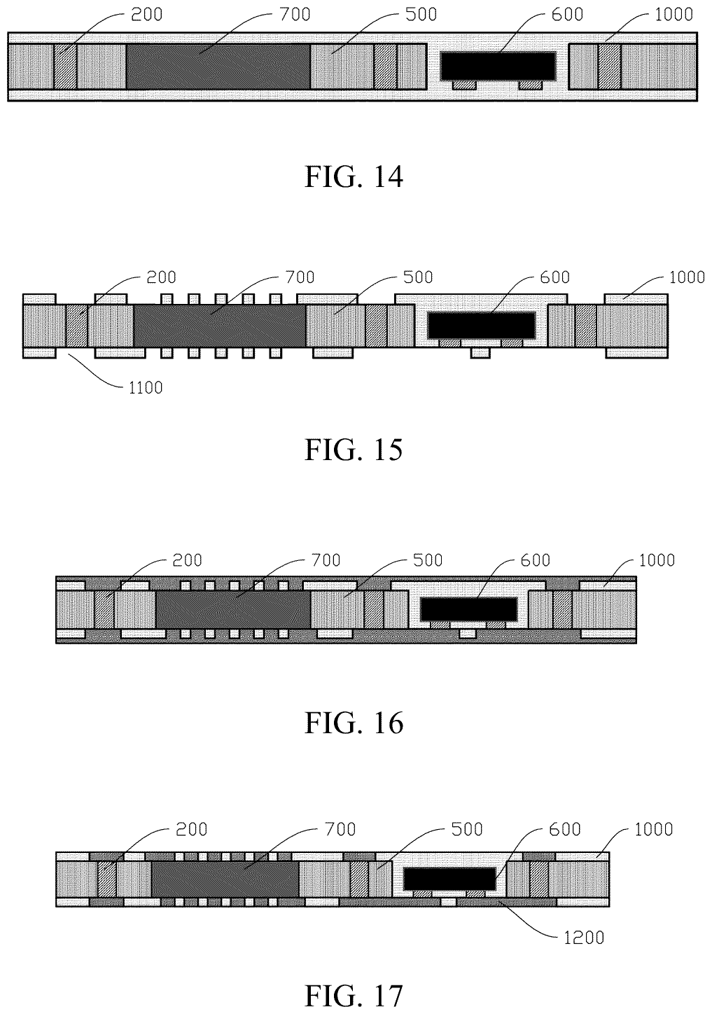

Specifically, as shown in FIG. 11, in order to mount the chip 600 inside the second mounting cavity 410, a bearing film 900 with certain adhesiveness is first attached to the bottom of the embedded magnet frame 800 for temporarily bearing the chip 600. As shown in FIG. 12, after the chip 600 is placed inside the second mounting cavity 410 and initially fixed through the bearing film 900, the chip 600 is packaged using the photosensitive resin film 1000, and the photosensitive resin film 1000 covers the upper surface of the first dielectric layer 500 while filling the second mounting cavity 410 at the same time. Subsequently, as shown in FIGS. 13 and 14, the bearing film 900 is removed, and the photosensitive resin film 1000 is laminated on the lower surface of the first dielectric layer 500.

As shown in FIG. 15, due to the characteristics of the photosensitive resin film 1000, the excess part of the photosensitive resin film 1000 can be removed by means of exposure, and the photosensitive resin film 1000 is opened with windows to form first windows 1100. As shown in FIG. 16, after opening windows, the first windows 1100 are filled with metal through Sputter seed layer production and electroplating filling. As shown in FIG. 17, the conductive metal layer on the surface of the photosensitive resin film 1000 is ground away to form required first circuits 1200 and/or bonding pads. The first circuit 1200 on the upper surface of the first dielectric layer 500 and the first circuit 1200 on the lower surface of the first dielectric layer 500 are connected by the conductive metal columns 200, and the first circuits 1200 are also electrically connected to the embedded magnet 700 and the chip 600, so as to complete the manufacturing of the embedded magnet integrated structure.

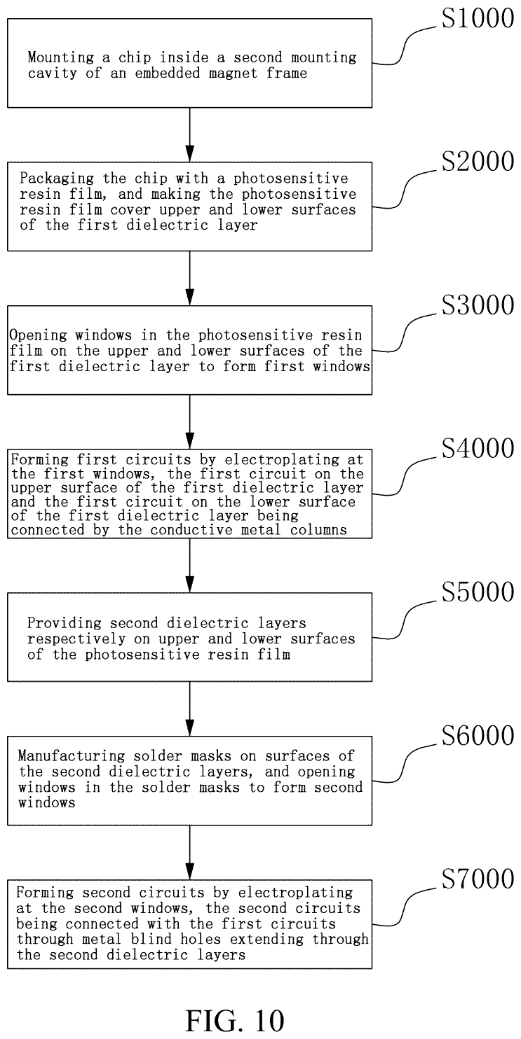

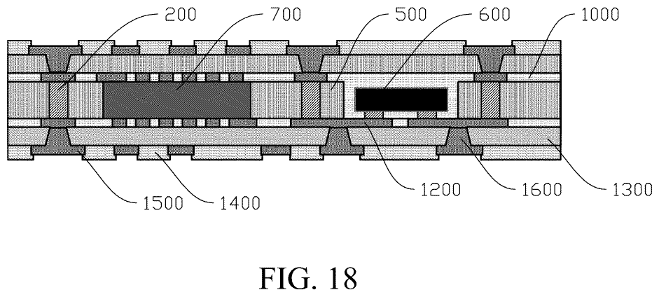

As shown in FIGS. 10 and 18, in some embodiments of the present disclosure, the manufacturing method for an embedded magnet integrated structure further includes the following steps:
Step S5000: providing second dielectric layers 1300 respectively on upper and lower surfaces of the photosensitive resin film 1000;
Step S6000: manufacturing solder masks 1400 on surfaces of the second dielectric layers 1300, and opening windows in the solder masks 1400 to form second windows; and
Step S7000: form second circuits 1500 by electroplating at the second windows, the second circuits 1500 being connected with the first circuits 1200 through metal blind holes 1600 extending through the second dielectric layers 1300.

Specifically, the above three steps are to further add layers to the embedded magnet integrated structure. Those of ordinary skills in the art can continue to add layers to the embedded magnet integrated structure on the basis of the above method according to actual needs. The specific number of layers can be selected according to actual needs.

In the manufacturing method for an embedded magnet integrated structure according to an embodiment of the present disclosure, by using the above embedded magnet frame 800, the embedded magnet 700 is already embedded inside the frame while the frame is being manufactured, thereby eliminating the need for subsequent secondary mounting of magnetic devices on the surface of the packaging substrate, saving production processes and production costs, preventing the alignment deviation between pins of the mounted devices and the packaging substrate, improving the fine wiring capabilities of the magnetic material integrated packaging substrate structure, and effectively improving the product yield. Moreover, the embedded magnet 700 is provided inside the frame, which is beneficial to achieving miniaturization and high integration of packaged products.

In another aspect, corresponding to the above manufacturing method for an embedded magnet integrated structure, an embodiment of the present disclosure further provides an embedded magnet integrated structure. As shown in FIG. 17, the embedded magnet integrated structure includes an embedded magnet frame 800, a chip 600, a photosensitive resin film 1000 and first circuits 1200. The chip 600 is provided in the second mounting cavity 410. The photosensitive resin film 1000 is filled in the second mounting cavity 410 to fix the chip 600, and the photosensitive resin film 1000 covers upper and lower surfaces of the first dielectric layer 500. The photosensitive resin film 1000 on the upper and lower surfaces of the first dielectric layer 500 is respectively provided with first windows 1100, the first circuits 1200 are provided in the first windows, and the first circuit 1200 on the upper surface of the first dielectric layer 500 and the first circuit 1200 on the lower surface of the first dielectric layer 500 are connected by the conductive metal columns 200.

Further, in some embodiments of the present disclosure, the embedded magnet integrated structure further includes second dielectric layers 1300, solder masks 1400 and second circuits 1500. The second dielectric layers 1300 are provided on the upper and lower surfaces of the photosensitive resin film 1000, and the second dielectric layers 1300 are provided with metal blind holes 1600 extending through the second dielectric layers 1300. The solder masks 1400 are provided on the surfaces of the second dielectric layers 1300, and the solder masks 1400 are provided with second windows. The second circuits 1500 are provided in the second windows, and the second circuits 1500 are electrically connected to the first circuits 1200 through the metal blind holes 1600.

According to the embedded magnet integrated structure provided in an embodiment of the present disclosure, the embedded magnet 700 is provided inside the first dielectric layer 500, thereby eliminating the need for subsequent secondary mounting of magnetic devices on the surface of the packaging substrate, saving production processes and production costs, preventing the alignment deviation between pins of the mounted devices and the packaging substrate, improving the fine wiring capabilities of the magnetic material integrated packaging substrate structure, and effectively improving the product yield. Moreover, the embedded magnet 700 is provided inside the frame, which is beneficial to achieving miniaturization and high integration of packaged products.

The embodiments of the present disclosure have been described in detail above with reference to the accompanying drawings. However, the present disclosure is not limited to the above embodiments. Within the scope of knowledge possessed by those of ordinary skill in the art, various modifications can be made without departing from the purpose of the present disclosure.

What is claimed is:

1. A manufacturing method for an embedded magnet frame, comprising:
manufacturing conductive metal columns, a first sacrificial block and a second sacrificial block on a surface of a bearing plate;
laminating a first dielectric layer on the surface of the bearing plate so that the first dielectric layer covers the conductive metal columns, the first sacrificial block and the second sacrificial block;
thinning the first dielectric layer to expose surfaces of the conductive metal columns, the first sacrificial block and the second sacrificial block;
etching the first sacrificial block and the second sacrificial block to form corresponding first and second mounting cavities, the second mounting cavity being used for mounting a chip;
filling the first mounting cavity with magnetic slurry to form an embedded magnet; and
removing the bearing plate to form the embedded magnet frame.

2. The manufacturing method for the embedded magnet frame according to claim 1, wherein the bearing plate comprises a substrate, and a first metal layer, a second metal layer and a third metal layer that are sequentially stacked on a surface of the substrate, and the first metal layer and the second metal layer are capable of being physically separated.

3. The manufacturing method for the embedded magnet frame according to claim 2, wherein the first metal layer and the second metal layer are copper layers, and the third metal layer is a titanium layer.

4. The manufacturing method for the embedded magnet frame according to claim 1, wherein the manufacturing conductive metal columns, a first sacrificial block and a second sacrificial block on a surface of a bearing plate comprises:
applying a photoresist layer on the surface of the bearing plate;
performing exposure and development process om the photoresist layer to form patterns corresponding to the conductive metal columns, the first sacrificial block and the second sacrificial block; and
forming, according to the patterns, the conductive metal columns, the first sacrificial block and the second sacrificial block by electroplating.

5. The manufacturing method for the embedded magnet frame according to claim 1, wherein the filling the first mounting cavity with magnetic slurry to form an embedded magnet comprises:
filling the magnetic slurry into the first mounting cavity by means of screen printing, and solidifying, grounding and polishing the magnetic slurry to form the embedded magnet.

6. A manufacturing method for an embedded magnet integrated structure, comprising:
mounting a chip inside a second mounting cavity of an embedded magnet frame, the embedded magnet frame being manufactured by the manufacturing method for the embedded magnet frame according to claim 1;
packaging the chip with a photosensitive resin film, and making the photosensitive resin film cover upper and lower surfaces of the first dielectric layer;
opening windows in the photosensitive resin film on the upper and lower surfaces of the first dielectric layer to form first windows; and
forming first circuits by electroplating at the first windows, the first circuit on the upper surface of the first dielectric layer and the first circuit on the lower surface of the first dielectric layer being connected by the conductive metal columns.

7. The manufacturing method for the embedded magnet integrated structure according to claim 6, further comprising:
providing second dielectric layers respectively on upper and lower surfaces of the photosensitive resin film;
manufacturing solder masks on surfaces of the second dielectric layers, and opening windows in the solder masks to form second windows; and
forming second circuits by electroplating at the second windows, the second circuits being connected with the first circuits through metal blind holes extending through the second dielectric layers.

8. An embedded magnet frame, comprising:
a first dielectric layer provided with a first mounting cavity and a second mounting cavity that extend through the first dielectric layer, the second mounting cavity being used for mounting a chip;
conductive metal columns extending through the first dielectric layer; and
an embedded magnet provided inside the first mounting cavity.

9. An embedded magnet integrated structure, comprising:
the embedded magnet frame according to claim 8;
the chip arranged in the second mounting cavity;
a photosensitive resin film filled in the second mounting cavity to fix the chip, the photosensitive resin film covering upper and lower surfaces of the first dielectric layer; and
first circuits, the photosensitive resin film on the upper and lower surfaces of the first dielectric layer being respectively opened with first windows, the first circuits being arranged in the first windows, and the first circuit on the upper surface of the first dielectric layer and the first circuit on the lower surface of the first dielectric layer being connected by the conductive metal columns.

10. The embedded magnet integrated structure according to claim 9, further comprising:
second dielectric layers provided on upper and lower surfaces of the photosensitive resin film, the second dielectric layers being provided with metal blind holes extending through the second dielectric layers;
solder masks provided on surfaces of the second dielectric layers, the solder masks being provided with second windows; and
second circuits provided in the second windows, the second circuits being electrically connected to the first circuits through the metal blind holes.
